(19) United States
(12) Patent Application Publication
(10) Pub. No.: US 2024/0232460 A1
(43) Pub. Date: Jul. 11, 2024

(54) MACHINE LEARNING FOR AUTONOMOUS VEHICLES USING PARAMETERIZABLE FEATURES

(71) Applicant: GM Cruise Holdings LLC, San Francisco, CA (US)

(72) Inventors: Alan Cruz, Bolingbrook, IL (US); Amit Karim, Washington, DC (US); Leftheris Kaleas, San Francisco, CA (US); Jeffrey Chan, Los Angeles, CA (US); David Witters, Westchester, CA (US); Justin DeCell, Issaquah, WA (US); Benjamin Goldstein, San Francisco, CA (US)

(73) Assignee: GM Cruise Holdings LLC, San Francisco, CA (US)

(21) Appl. No.: 18/150,597

(22) Filed: Jan. 5, 2023

(51) Int. Cl. G06F 30/20

(52) U.S. Cl. CPC G06F 30/20

(57) ABSTRACT

Examples of the present disclosure provide a computer-implemented system, comprising instructions for performing operations including: retrieving real-world data comprising skeleton attributes of various skeletons; receiving instructions to generate a simulated skeleton for a scene in a simulation; generating the simulated skeleton according to the scene based on the skeleton attributes, the simulated skeleton comprising a generic skeleton modified by scaling factors according to the scene; building a simulation asset using the simulated skeleton; and determining a reaction of a vehicle to the simulation asset in the scene simulated, the reaction of the vehicle being a function of a configuration of the vehicle.

### BACKGROUND

### 1. Technical Field

The present disclosure generally relates to autonomous vehicles (AVs) and, more specifically, machine learning for AVs using parameterizable skeletons, attributes, and appearance features.

### 2. Introduction

An AV also known as a self-driving car, driverless vehicle, and robotic vehicle, is a motorized vehicle that can navigate without a human driver. AVs use multiple sensors to sense the environment and move without human input. Sensors in an exemplary AV can include a camera sensor, a light detection and ranging (LIDAR) sensor, and a radio detection and ranging (RADAR) sensor, among others. The sensors collect data and measurements that the AV can use for operations such as navigation. The sensors can provide the data and measurements to an internal computing system of the AV, which can use the data and measurements to control a mechanical system of the AV, such as a vehicle propulsion system, a braking system, or a steering system. Typically, the sensors are mounted at fixed locations on the AVs. The automation technology in the AVs may also enable the vehicles to drive on roadways and to accurately and quickly perceive the vehicle's environment, including obstacles, signs, and traffic lights. Autonomous technology may utilize map data that can include geographical information and semantic objects (such as parking spots, lane boundaries, intersections, crosswalks, stop signs, traffic lights) for facilitating the vehicles in making driving decisions. The vehicles can be used to pick up passengers and drive the passengers to selected destinations. The vehicles can also be used to pick up packages and/or other goods and deliver the packages and/or goods to selected destinations.

### BRIEF DESCRIPTION OF THE DRAWINGS

The various advantages and features of the present technology will become apparent by reference to specific implementations illustrated in the appended drawings. To facilitate this description, like reference numerals designate like structural elements. A person of ordinary skill in the art will understand that these drawings only show some examples of the present technology and would not limit the scope of the present technology to these examples. Furthermore, the skilled artisan will appreciate the principles of the present technology as described and explained with additional specificity and detail through the use of the accompanying drawings in which:

FIG. 1 illustrates a simplified block diagram of an example computer implemented system for machine learning for AVs using parameterizable skeletons, attributes, and appearance features, according to some examples of the present disclosure;

FIG. 2 illustrates a simplified block diagram of an example operation of a computer implemented system for machine learning for AVs using parameterizable skeletons, according to some examples of the present disclosure;

FIG. 3 illustrates a simplified block diagram of an example computer implemented system for machine learning for AVs using parameterizable skeletons, according to some examples of the present disclosure;

FIG. 4 illustrates a simplified flow diagram illustrating various operations that may be associated with an example computer implemented system for machine learning for AVs using parameterizable skeletons, according to some examples of the present disclosure;

FIGS. 5A and 5B illustrates simplified user interfaces of a computer implemented system for machine learning for AVs using parameterizable attributes, according to some examples of the present disclosure, according to some examples of the present disclosure;

FIG. 6 illustrates a simplified block diagram of an example computer implemented system for machine learning for AVs using parameterizable appearance features, according to some examples of the present disclosure;

FIG. 7 illustrates a simplified flow diagram illustrating various operations that may be associated with an example computer implemented system for machine learning for AVs using parameterizable attributes and appearance features, according to some examples of the present disclosure;

FIG. 8 illustrates a simplified flow diagram illustrating various operations that may be associated with an example computer implemented system for machine learning for AVs using parameterizable skeletons and attributes, according to some examples of the present disclosure;

FIG. 9 illustrates a simplified flow diagram illustrating various operations that may be associated with an example computer implemented system for machine learning for AVs using parameterizable skeletons, attributes, and appearance features, according to some examples of the present disclosure;

FIG. 10 illustrates an example system environment that can be used to facilitate AV dispatch and operations, according to some aspects of the disclosed technology; and

FIG. 11 is a simplified block diagram illustrating various components associated with a computer implemented simulation system for an AV, according to some examples of the present disclosure.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form in order to avoid obscuring the concepts of the subject technology.

AVs can provide many benefits. For instance, AVs may have the potential to transform urban living by offering opportunities for efficient, accessible, and affordable transportation. An AV may be equipped with various sensors to sense an environment surrounding the AV and collect information (e.g., sensor data) to assist the AV in making driving decisions. To that end, the collected information or sensor data may be processed and analyzed to determine a perception of the AV's surroundings, extract information related to navigation, and predict future motions of the AV and/or other traveling agents in the AV's vicinity. The predictions may be used to plan a path for the AV (e.g., from a starting position to a destination). As part of planning, the AV may access map information and localize itself based on location information (e.g., from location sensors) and the map information. Subsequently, instructions can be sent to a controller to control the AV (e.g., for steering, accelerating, decelerating, braking, etc.) according to the planned path.

The operations of perception, prediction, planning, and control at an AV may be implemented using a combination of hardware and software components. For instance, an AV stack or AV compute process performing the perception, prediction, planning, and control may be implemented as software code or firmware code. The AV stack or AV compute process may be executed on processor(s) (e.g., general processors, central processors (CPUs), graphical processors (GPUs), digital signal processors (DSPs), ASIC, etc.) and/or any other hardware processing components on the AV. Additionally, the AV stack or AV compute process may communicate with various hardware components (e.g., on-board sensors and control system of the AV) and/or with an AV infrastructure over a network.

Training and testing AVs in the physical world can be challenging. For instance, to provide good testing coverage, an AV may be trained and tested to respond to various driving scenarios (e.g., millions of physical road test scenarios) before it can be deployed in a real-life roadway system. As such, it may be costly and time-consuming to train and test AVs on physical roads. Furthermore, there may be test cases that are difficult to create or too dangerous to cover in the physical world. Accordingly, it may be desirable to train and validate AVs in a simulation environment.

A simulator may simulate (or mimic) real-world conditions (e.g., roads, lanes, buildings, obstacles, other traffic participants, trees, lighting conditions, weather conditions, etc.) so that an AV may be tested in a virtual environment that is close to a real physical world. As used herein and as is commonly known in the art, the terms “simulated environments,” “simulated,” “virtual,” and “virtual reality environment” may refer to environments, algorithms with instructions for a computing processor, or video displays comprising computer-generated virtual objects or computer-generated virtual objects that are added to a display of a real scene, and may include computer-generated icons, images, or virtual objects. The simulation necessarily involves execution of instructions by a processor, and an output of the simulation may comprise various settings of the AV that enabled its reaction in the simulation to a particular virtual reality environment.

Testing AVs in a simulator can be more efficient and allow for creation of specific traffic scenarios. To that end, the AV compute process implementing the perception, prediction, planning, and control algorithms can be developed, validated, and fine-tuned in a simulation environment. More specifically, the AV compute process may be executed in an AV simulator (simulating various traffic scenarios), and the AV simulator may compute metrics related to AV driving decisions, AV response time, etc. to determine the performance of an AV to be deployed with the AV compute process. Further, it is advantageous in a simulation to be able to automatically enter as many parameters as desired to generate thousands of interesting and rare scenarios against which the AVs can be tested. Reliance on costly real-world testing can be reduced considerably particularly in case of events that happen rarely, that take thousands of road miles to test properly (if at all), and thus, are not scalable.

Accordingly, examples of the present disclosure provide for a simulator that can perform various operations including: retrieving real-world data comprising human height, length of limbs and torso, and such other information that contribute to skeleton attributes of various real-world skeletons; receiving instructions to generate a simulated skeleton for a scene in a simulation; generating the simulated skeleton according to the scene based on the skeleton attributes, the simulated skeleton comprising a generic skeleton modified by scaling factors according to the scene; building a simulation asset using the simulated skeleton; determining a reaction of an AV to the simulation asset in the scene simulated, the reaction of the AV being a function of a configuration of the AV; and in response to the reaction, updating the configuration. “Configuration of the AV” as used herein refers to settings of software modules and hardware components of the AV. The operations of determining the reaction and updating the configuration are repeated until a desired reaction is obtained. A final updated configuration corresponding to the desired reaction is then updated to a physical AV.

In another aspect of the present disclosure, a method is provided, the method comprising: retrieving, by a computer-implemented system, real-world data comprising skeleton attributes of various skeletons, each skeleton comprising a digital hierarchical framework of bones, the skeleton attributes comprising at least a dimension of each bone; generating, by the computer-implemented system, skeleton sets from the skeleton attributes, bones in each skeleton set being categorized into respective distributions; and saving, by the computer-implemented system, the skeleton sets in a skeleton data lake.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life manufacturing limitations which may cause the features to not look so “ideal” when any of the structures described herein are examined minutely. Note that in the figures, various components are shown as aligned merely for ease of illustration; in actuality, some or all of them may be misaligned. Further, the figures are intended to show relative arrangements of the components within their assemblies, and, in general, such assemblies may include other components that are not illustrated (e.g., various other components related to electrical functionality, or thermal mitigation). For example, in some further examples, the assembly as shown in the figures may include more electrical or thermomechanical components. Additionally, although some components of the assemblies are illustrated in the figures as being planar rectangles or formed of rectangular solids, this is simply for ease of illustration, and examples of these assemblies may be curved, rounded, or otherwise irregularly shaped as dictated by and sometimes inevitable due to the manufacturing processes used to make various components.

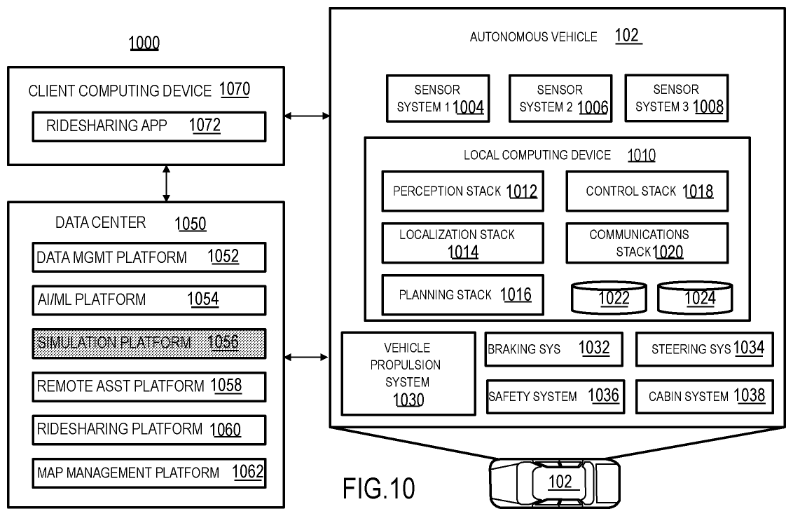

For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 112a-112e), such a collection may be referred to herein without the letters (e.g., as “112”).

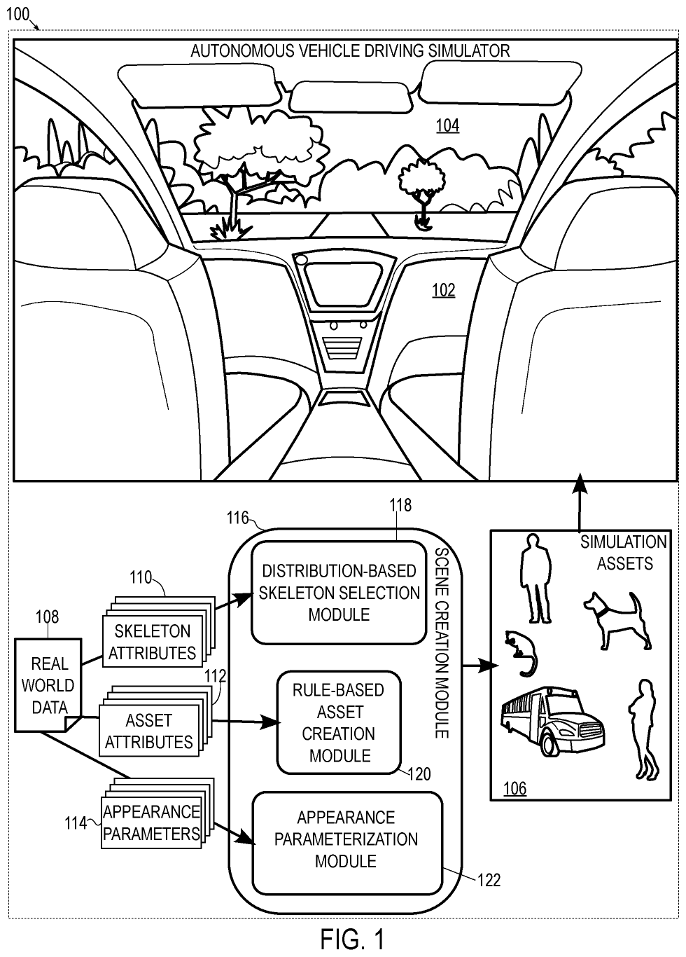

FIG. 1 illustrates a simplified block diagram of an example computer implemented system 100 for machine learning for an AV 102 using parameterizable skeletons, attributes, and appearance features. System 100, also referred to herein as a simulator 100, can create a virtual environment of a scene 104 in which a virtual model of AV 102 can operate with various vehicle configurations, such as speed, acceleration, braking, lights, etc. Scene 104 may be populated with various simulation assets 106, such as trees, roads, bystanders, pets, other vehicles, buildings, rocks, debris, puddles, and any other objects that may be selected and configured according to the methods described herein to enable learning and tuning of AV configurations for AV 102. Simulator 100 can not only be used to test for safety, but also for scaling to new locations (e.g., cities, streets, neighborhoods, etc.) without having to perform millions of miles of real-world driving tests on the road.

Note that although user interface views are shown in the figure and described, and such visualizations are helpful to debug and analyze a given simulation, simulator 100 may execute simulations without any storage in a “road bag,” comprising a collection of data messages generated by simulated sensors as and when they perceive the simulated world in the form of geometric surfaces and textures. It is to be understood that the description of a rendered image herein also encompasses such unrendered animations to the extent that they impact the configurations of various sensors and operations of simulated AV 102. In a general sense, the perception suite in AV 102, whether real-world or simulated, makes use of broad sensor data from a variety of sensors, such as LiDAR, radar and camera. In some examples, coarse-grained detections are derived primarily from LiDAR and radar images and fine-grained detections are derived from camera images.

In various examples, simulator 100 may include maps of various localities, such as cities. Scenes 104 may be created using such maps to ensure fidelity to real-world data 108. Scenes 104 may be created to simulate changes to the environment such as lane changes, street closures, construction, adverse weather events such as heavy rain, fog, etc. Such scenes 104 may enable testing out new operational design domains and determining optimum AV configurations for the simulated conditions. As used herein, an “operational design domain” is a description of various specific operating conditions in which AV 102 is configured to properly operate, including but not limited to roadway types, speed range, environmental conditions (e.g., weather, daytime/nighttime, etc.), prevailing traffic law and regulations, and other such constraints. In various examples, simulator 100 may combine information from perception with heuristics learned from real-world data 108 to recreate a simulation environment that is based on actual road information and real-world conditions. Further, simulator 100 uses machine learning to automatically enter numerous parameters to generate thousands of different scenarios against which AV 102 can be tested. For example, an event that happens rarely may take hundreds of thousands of road miles to test properly if at all, but in a simulated environment, such rare events can be scalably explored by setting appropriate parameters to generate test scenarios.

In many examples, test scenarios may also include ways in which other road users, such as bystanders, school buses or emergency vehicles react to AV 102, or in which AV 102 reacts to other road users. For example, the height of various bystanders may vary depending on the geographical location (e.g., bystanders in Region A may be shorter than bystanders in Region B). Real-world data 108 may comprise measurements of various humanoid dimensions, such as length of various limbs, overall height, etc. and such measurements may be entered as part of skeleton attributes 110 into a scene creation module in simulator 100. In another example, a traffic police officer's uniform and pose (e.g., hand gesture to stop a vehicle) could vary depending on the type of traffic police officer, or the location of the traffic police officer (e.g., a traffic police officer's uniform and pose in City A in Country B may be different from another traffic police officer's uniform and pose in City C in Country D). Such asset attributes 112, which form part of real-world data 108 may be entered into scene creation module 116.

In yet another example, simulator 100 can simulate the flashing lights of school buses or emergency vehicles within a nominal range of real-world data of such flashing lights and then use the simulation to improve detections in a real-world AV 102. For example, simulations in simulator 100 can enable determining the frequency of flashing at which the machine learning model is a close approximation to real-world frequency within acceptable margins of error. To this end, actual frequencies of various types of school buses and emergency vehicles may be measured and entered as appearance parameters 114 into scene creation module 116 to generate appropriate scene 104 to test sensor configurations of AV 102. In yet another example, lighting at a particular location at various unique times of day and weather conditions may be measured and such measurements entered as appearance parameters 114 into scene creation module 116. In various examples, such simulations can enable generating synthetic data for configuring AV 102. A suitable mix of synthetic and real-world data 108 may enable increasing by an order of magnitude or more, provision of relevant data sets for configuration of AV 102. Moreover, by providing many procedurally generated scenes 104, efficient tuning of AV configurations may be facilitated at an affordable cost.

In various examples, scene selection module 116 may include various modules therein for facilitating creation of scenes 104. In a particular example, a distribution-based skeleton selection module 118 can enable generating appropriate humanoid skeletons for creating simulation assets 106 based on skeleton attributes 110. A rule-based asset creation module 120 can enable generating appropriate attributes for the skeletons of simulation assets 106 using asset attributes 112. An appearance parameterization module 122 can enable tailoring sensory appearance of simulation assets 106 using appearance parameters 114. In various examples, appearance parameters 114 include output from any sensor on AV 102, such as camera, LiDAR, radar, etc. Such suitably tailored simulation assets 106 may be used to generate scenes 104 to test various AV configurations of AV 102.

In some examples, a multiplicity of objects may be simulated in scene 104. For example, scene 104 may be composed of many objects represented by corresponding simulation assets 106 that have parameters set according to preconfigured rules (e.g., from a random distribution, according to a preconfigured prediction, etc.). The combination of all the possible independent parameters that can be set represents a high-dimensional space in simulator 100. A collection of scenes 104 may be stored by simulator 100, each scene 104 including simulation assets 106 that span the high-dimensional space of parameters, such that simulation assets 106 are widely distributed in the high-dimensional parameter space, for example to allow AV 102 to sense as much variety as possible in the collection of scenes 104 with many different simulation assets 106. Because each parameter can have many values (in some cases infinite values), generating scene 104 with every possibility of each parameter may be computationally expensive, so as to be unfeasible from cost and/or time considerations. In some examples, many scenes 104 may be generated at once with the same type of simulation asset 106, each scene 104 differing according to the preconfigured sampling rule for the parameters of each simulation asset 106. Such methodology can allow sampling a wide variety of parameters for the same object represented by the corresponding simulation asset 106, so that at least some samples may include those that are “far away” from what was generated for that object in a different scene. Thus, a collection of various scenes 104 may capture a practically diverse variety of particular types of simulation assets 106 for AV 102. Additionally, dependencies between some parameters may also guide the values that can be set for them.

In a specific example, scene selection module 116 may be implemented on various compute engine virtual machines in a cloud computing paradigm using containerized applications managed by an appropriate system that automates deployment, scaling, and management. Real-world data 108 from camera, LiDAR, radar and other sensor systems is fed to a cloud storage. Using appropriate artificial intelligence algorithms for scene understanding, various features of any real-world scene are automatically labeled and tagged with many different classes of events, attributes and parameters, generating, for example, skeleton attributes 110, asset attributes 112, and appearance parameters 114. From there, highly scalable extract-transform-load (ETL) pipelines and data lakes are used to create and extract petabytes of data quickly and efficiently for scene selection module 116. Leveraging a suitably configured database, several exabytes of data can be processed across several million queries to generate appropriate scene 104 with suitably parameterized simulation assets 106. Generation of scene 104 may use continuous learning machines to actively mine real-world data 108 to automatically train new models that exceed performance (e.g., predictability) of older models. Simulator 100 uses scenes 104 to recreate any on-road event without manual intervention. Thus, before AV 102 hits the road, it will have been driving in simulation beforehand, encountering and learning from countless long-tail events in the cloud.

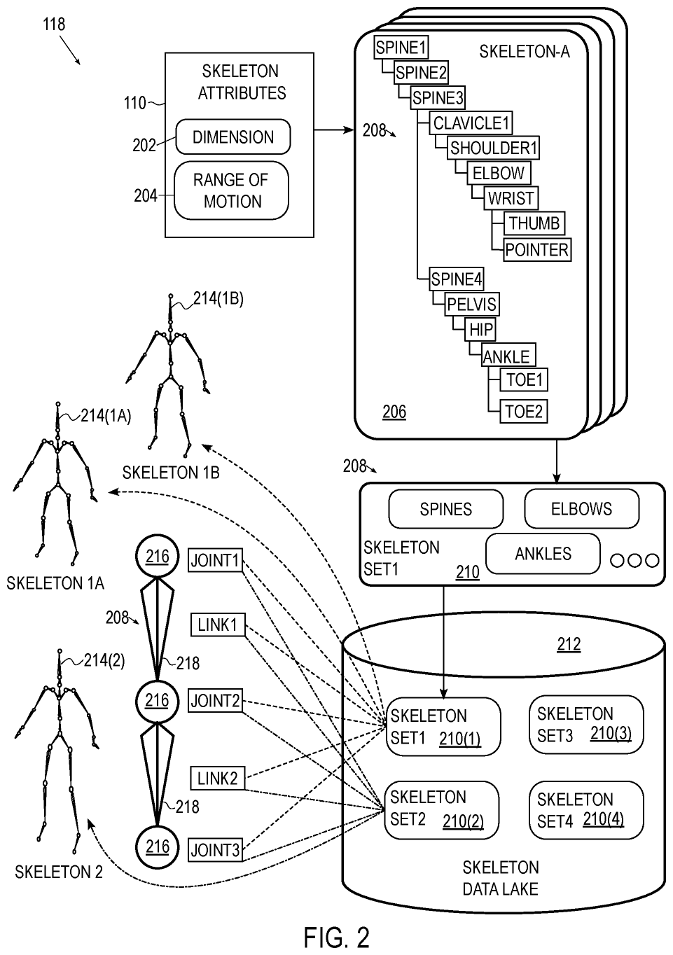

FIG. 2 illustrates a simplified block diagram of an example operation of a computer implemented system for machine learning for AVs using parameterizable skeletons 206, according to some examples of the present disclosure. Although various examples are described in relation to humanoid skeletons, it may be appreciated that such methods and techniques may be used for non-humanoid skeletons without departing from the scope of the present disclosure. Distribution-based skeleton selection module 118 uses skeleton attributes 110 as inputs. Skeleton attributes 110 comprises dimensions 202 and range of motion 204 of various bones in a human body. Other real-world measurements pertaining to skeleton sizes and behavior may be included in skeleton attributes 110 within the broad scope of the disclosure herein.

As used herein, the term “skeleton” refers to a digital hierarchical framework of bones 208 in an simulation asset 106. Skeleton 206 mimics a real biological skeleton in its structure. For example, the various types of bones 208 in skeleton 206 may include, by way of examples and not as limitations, spine, shoulder, clavicle, arm, thumb, etc. and the joints associated therewith. Each bone 208, which can either be a joint or a link combined with other bones 208 according to the rules of the digital hierarchical framework of skeleton 206. Thus, for example, an arm-link can be connected only to a shoulder-joint, and not to a pelvic joint; the arm-link can be connected on one end to the shoulder-joint and on another end to an elbow-joint; and so on. Each bone 208 may have associated therewith certain dimension 202 and range of motion 204 of a real-world human.

A particular skeleton 206, for example Skeleton-A may comprise a hierarchical framework of bones 208 of a particular human whose skeleton attributes 110 are captured from real-world data 108. Each skeleton 206 may correspond to a distinct and unique human. Several such skeletons 206 may be collected into a skeleton set 210, for example SKELETON SET1, according to a distribution. Examples of distributions include skeletons (or humanoids) corresponding to people of Region A; skeletons (or humanoids) corresponding to people from town B; skeletons (or humanoids) corresponding to men from city C; skeletons (or humanoids) corresponding to women in Country D; and so on. Each such distribution may correspond to a separate skeleton set 210 in some examples. In some other examples, any one skeleton set 210 may include bones 208 from skeletons 206 according to more than one distribution. The criterion (or criteria) for any distribution may be based on any desired rule or characteristic based on particular needs within the broad scope of the disclosure herein.

Skeleton set 210 may comprise a collection of various bones 208 that may be unconnected to particular skeletons 206, but are part of a unique, or separate distribution. Different skeleton sets for example, 210(1), 210(2), 210(3), 210(4) may include bones having correspondingly different distributions (e.g., a clavicle in skeleton set 210(1) may follow a different distribution than a clavicle in skeleton set 210(2)). For example, skeleton set 210(1), SKELETON SET1, may comprise bones 208 belonging to men from Region A. A clavicle in skeleton set 210(1) may belong to a distribution of clavicles for that particular population, ranging in dimensions 202 between a minimum and a maximum and connected to corresponding joints having ranges of motions 204 between a minimum and a maximum according to that population. A different skeleton set 210(2), for example SKELETON SET2 may have bones 208 following a different distribution, and corresponding dimensions 202 and ranges of motion 204 of such bones 208 may be different from those of Skeleton set1. Note that only four skeleton sets 210(1)-210(4) are shown for ease of illustration; any number of skeleton sets 210 may be included in skeleton data lake 212 within the broad scope of the disclosure herein.

In various examples, each bone 208 in any one skeleton 206 may be identified by a matching identifier, such as “clavicle,” “tibia,” “femur,” etc. Although descriptive identifiers are noted herein, it is to be understood that any suitable identifier, including numbers and letters, may be used within the broad scope of the disclosure herein. Corresponding bones 208 in separate skeletons 206 may share the matching identifier. Thus, for example, a “femur” may be attached to a “pelvic bone” in substantially all skeletons 206. Bones 208 from various skeletons 206 may be grouped into respective distributions according to the corresponding matching identifiers. Thus, for example, all bones 208 with the identifier “femur” in any one skeleton set 210 are grouped into a common distribution. Because such data consists of real-world data 108, such bones 208 with the identifier “femur” will have different dimensions reflecting the real-world measurements. The resulting distribution of bones 208 having identifier “femur” thus has statistical attributes such as a minimum dimension, a maximum dimension, a range, a standard deviation, etc. derived from corresponding skeleton attributes 110.

A plurality of such skeleton sets 210 may be collected into a skeleton data lake 212. In some examples, skeleton data lake 212 may comprise a database of structured datasets. In other examples, skeleton data lake 212 may comprise a repository of structured, semistructured and unstructured data. In various examples, skeleton data lake 212 may provide a scalable and secure platform that allows scene creation module 116 to ingest real-world data 108 from any system at any speed, irrespective of the location and type of the system and store real-world data 108 and skeleton sets 210 in full fidelity, without loss of information, allowing data to be processed in real-time or batch mode. In some examples, skeleton sets 210 may be stored in skeleton data lake 212 in native format with appropriate tags and metadata; in other examples, skeleton sets 210 may be formatted into one or more data structures according to a hierarchical architecture and stored in skeleton data lake 212.

A particular simulated skeleton 214(1A) (e.g., Skeleton 1A) may be generated from randomly selected bones 208 of a particular one of skeleton set 210, for example SKELETON SET1. Note that simulated skeleton 214 comprises a simulation of a kinematic rigging comprising links, linkages (open and closed), hinges, and various types of joints having varying degrees of freedom according to their use and/or behavior in a real-world skeleton. Thus, such skeleton 214(1A) may include joints 216 and connected links 218, each one of which is randomly selected from the same skeleton set 210 and joined together according to the hierarchical framework of generic skeleton 206. The hierarchical framework may provide the rules of coupling together disparate, randomly selected bones 208. The selected skeleton set 210 may provide the dimensions and ranges of motion of particular bones 208 selected for generating skeleton 214(1A). For example, a knee joint may be coupled to a femur on one side and a tibia on the other side based on the hierarchical framework of generic skeleton 206, each such knee joint, femur, and tibia being selected randomly from a first collection of knee joints, a second collection of femurs and a third collection of tibiae in skeleton set 210 to generate simulated skeleton 214(1A).

Another simulated skeleton 214(1B) (e.g., Skeleton 1B) may be generated from randomly selected bones 208 of same skeleton set 210 as simulated skeleton 214(1) but may nevertheless have different shape and size than simulated skeleton 214(1A) because individual bones 208 are differently sized or have different ranges of motion. However, both simulated skeletons 214(1A) and 214(1B) will fall within the distribution of common skeleton set 210, for example, population of men in Region A.

Yet another simulated skeleton 214(2) (e.g., Skeleton 2) may be generated from randomly selected bones 208 of different skeleton set 210, for example, SKELETON SET2, corresponding to men in Region B. Skeleton 214(2) may have different shape and size than either simulated skeleton 214(1A) or simulated skeleton 214(1B) because each individual bone in simulated skeleton 214(2) belongs to a different distribution. Thus, based on a particular map selected for scene 104, simulation assets 106, for example bystanders, may be generated according to simulated skeletons 206 suitable for such scene 104. In one such example, a simulation of scene 104 set in Region A may include male bystanders whose simulated skeletons 214 are generated from skeleton set 210 for such distribution; on the other hand, another simulation of scene 104 in Region B may include male bystanders whose simulated skeletons 214 are generated from skeleton set 210 for such other distribution. Such close fidelity to real-world data 108 can enable more accurate simulations and increase relevance and accuracy of corresponding configurations for AV 102.

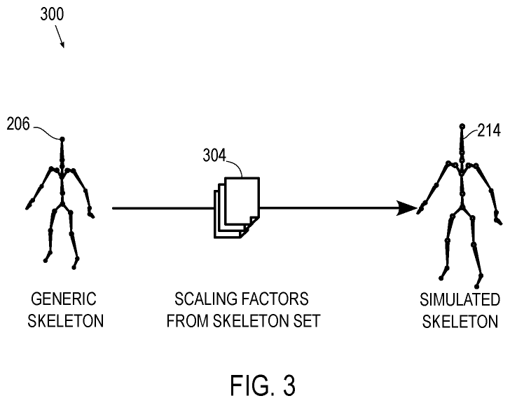

FIG. 3 illustrates a simplified block diagram of an example transformation operation 300 for machine learning for AVs using parameterizable skeletons 206, according to some examples of the present disclosure. Generic skeleton 206 may be transformed to simulated skeleton 214 by scaling factors 304 randomly selected from one of skeleton set 210. Scaling factors 304 may comprise a ratio of a randomly selected value for the range of bone dimensions (and/or range of motion) of the particular bone in skeleton set 210 to the dimension (and/or range of motion) of the corresponding bone of generic skeleton 206. In various examples, the generic bones of generic skeleton 206 may have respective preconfigured dimensions and/or range of motion. Scaling factors 304 may be different for different bones 208.

For example, a particular one of skeleton set 210 may comprise bones 208 of men in Region A. Each bone type in skeleton set 210 may follow a separate distribution: tibia length for men in Region A may vary between 30.94 cm and 38.92 cm in skeleton set 210 and femurs may vary between 36.91 cm and 46.40 cm. Generic skeleton 206 may have a tibia length of 36.45 cm and a femur length of 48 cm. Scaling factor 304 for the tibia may be calculated as 0.85, which is obtained by selecting a random value 31 between 30.94 and 38.92 and determining a ratio of the random value 31 to generic skeleton tibia length 36.45. Scaling factor 304 for the femur may be calculated as 0.79, which is obtained by selecting a random value 39 between 36.91 and 46.4 and determining a ratio of the random value 39 to generic skeleton femur length 48. Final simulated skeleton 214 thus has a shape of generic skeleton 206 with tibia scaled by 0.85 to 31 cm and femur scaled by 0.79 to 39 cm. The process may be followed for each bone 208 in generic skeleton 206 to complete simulated skeleton 214. Thus, simulated skeleton 214 may comprise individual bones 208 falling within ranges of respective distributions in skeleton set 210. The collective possible combinations of simulated skeletons 214 that can be derived thus can encompass a wide range of possible humanoid skeletons of men in Region A, providing close fidelity to real-world observations without having to rely completely on actual measured data in simulating scene 104 by simulator 100.

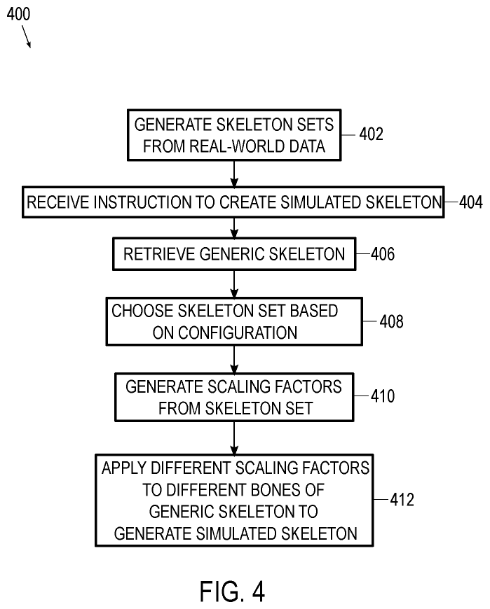

FIG. 4 illustrates a simplified flow diagram illustrating various operations 400 that may be associated with an example computer implemented system for machine learning for AVs using parameterizable skeletons, according to some examples of the present disclosure. At 402, skeleton sets 210 may be generated by scene creation module 116 from real-world data 108 comprising skeleton attributes 110. At 404, distribution-based skeleton selection module 118 may receive instructions to create simulated skeleton 214. In some examples, the instructions may be received from a user through a command-line interface (CLI) pipeline. In another example, the instructions may be received from scene creation module 116, which in turn received instructions from another module, for example, to create scene 104; in such examples, scene creation module 116 may generate particular instructions to internal modules to generate respective simulation assets 106 based on the received instructions. The particular instructions to distribution-based skeleton selection module 118 may comprise instructions to create simulated skeleton 214 according to a particular configuration of scene 104, for example, an event transpiring at a busy pedestrian crossing in City A.

At 406, distribution-based skeleton selection module 118 may retrieve generic skeleton 206. At 408, a particular one of skeleton set 210 may be selected by distribution-based skeleton selection module 118 based on the configuration received in the instructions. At 410, distribution-based skeleton selection module 118 may apply scaling factors 304 to generic skeleton 206, as described in reference to FIG. 3. At 412, distribution-based skeleton selection module 118 may apply different scaling factors 304 to different bones 208 of generic skeleton 206 to generate simulated skeleton 214.

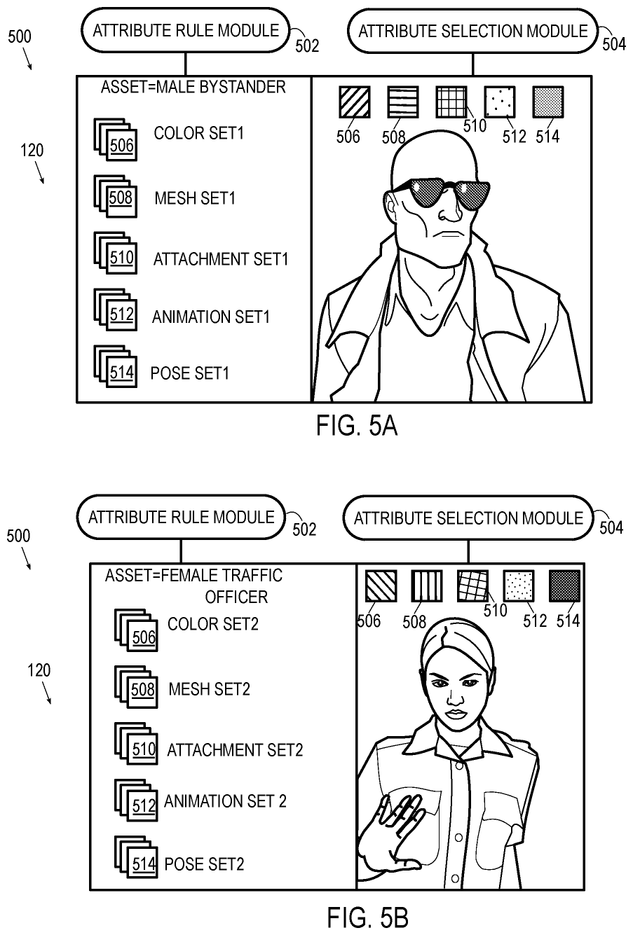

FIGS. 5A and 5B illustrates simplified user interface 500 of a computer implemented system for machine learning for AVs using parameterizable attributes, according to some examples of the present disclosure. Rule-based asset creation module 120 may comprise an attribute rule module 502 and an attribute selection module 504. Attribute rule module 502 may take as input real-world data 108 comprising asset attributes 112 and generate rules for particular asset attributes based on corresponding attribute distributions. Different attribute distributions may have correspondingly different attribute rules.

In some examples (as shown in the figures), attribute rule module 502 may generate rules for asset attributes 112 comprising color 506 (e.g., color of various parts of simulation asset, for example, hair, clothes, etc.), mesh 508 (e.g., type of simulation asset, whether male, female, construction worker, traffic officer, etc.), attachment 510 (e.g., coat, hat, sunglasses, badge, etc.), animation 512 (e.g., simulation asset crossing the street, walking along sidewalk, running across the road, etc.) and pose 514 (e.g., stop gesture, move gesture, look away, look toward, etc.) for a distribution of certain characters (e.g., male bystander, female traffic officer, sidewalk runner, etc.) in City A. Other asset attributes 112 may be included within the broad scope of the disclosure herein. As used herein, the term “character” refers to simulation asset 106 having a particular subset of asset attributes 112. Thus, each simulation asset 106 may be associated with a distinct attribute distribution in simulator 100; each attribute distribution used by simulator 100 may have a distinct subset of asset attributes 112. In some examples, any one asset attribute 112 may be associated with a separate asset distribution; in some examples, any one asset distribution may be associated with a subset of asset attributes 112, or substantially all asset attributes 112.

A particular simulation asset 106, say a male bystander as shown in FIG. 5A, selected by scene creation module 116, may be assigned certain asset attributes 112, which may change depending on the configuration of scene 104. For example, a scene of an event at a busy pedestrian crossing in City A may have male bystanders having different asset attributes 112 than in another scene of the same event along a less crowded street in City B.

Attribute rule module 502 may inspect asset attributes 112 and generate appropriate rules for various asset attributes 112, which are derived from asset attributes 112. Attribute rule module 502 may collate them into suitable attribute sets. The respective attribute sets generated by attribute rule module 502 may follow certain distribution-based rules. In some examples, the asset attributes may be grouped into attribute sets based on a frequency of appearance of certain asset attributes 112 in the attribute distribution. For example, a distribution of traffic officers according to real-world data 108 may result in a rule that traffic officers do not wear construction hats, and that certain types of hats are used exclusively by traffic offers. Another distribution-based rule may comprise meshes, for example, a female mesh is not to be used for a male bystander. Yet another example of a distribution-based rule is that female bystanders in Region A may wear a kimono but a female bystander in Region B may not, so that attachment sets for female bystanders in Region A can include the kimono among various selections, whereas attachment sets for female bystanders in Region B do not include the kimono. Attribute selection module 504 may select a random one from each attribute set to generate the final simulation asset 106.

For example, asset attributes 112 of a male bystander at a busy intersection in City A may be associated with a color set1, mesh set1, attachment set1, animation set1 and pose set1. Attribute selection module 504 may select a particular one of color 506 from color set1, another particular one of mesh 508 from mesh set1, yet another particular one of attachment from attachment set1, yet another particular one of animation 512 from animation set1 and yet another particular one of pose 514 from pose set1. The resulting simulation asset 106 may be a bald man with dark glasses, tan overcoat, gray shirt, who walks across the zebra crossing from left to right while looking away from AV 102. Another male bystander may have different asset attributes 112 based on the random selections by attribute selection module 504 from the same sets of asset attributes 112.

On the other hand, for a different simulation asset 106, say a female traffic officer as shown in FIG. 5B, attributes color 506, mesh 508, attachment 510, animation 512 and pose 514 may be selected by attribute selection module 504 from entirely different sets of asset attributes 112 than those for the male bystander of FIG. 5A. The sets of asset attributes 112 for the female traffic officer may comprise color set2, mesh set2, attachment set2, animation set2 and pose set2. The resulting simulation asset 106 may be a young woman in blue uniform without a hat, standing in front of AV 102, looking at AV 102, her hands raised in a stop gesture.

In various examples, rule-based asset creation module 120 may enable generating simulation assets 106 without any human intervention, based on real-world data 108 relevant to scene 104 being simulated. Settings of scene 104 may indicate one of more attribute distributions (e.g., bystanders, shopkeepers, bicyclists, etc.). A distinct subset of asset attributes 112 may be associated with each attribute distribution. Attribute rule module 502 may identify a particular one of the attribute distributions indicated by the settings of scene 104, identify the subset of asset attributes 112 associated with the identified attribute distribution and retrieve the derived attribute rules associated with the subset of asset attributes 112. The attribute rules may enable generating asset attributes 112 that are grouped into distinct attribute sets in some cases (i.e., different attribute sets can be generated for separate cones of the attribute distributions according to the attribute rules).

For example, an attribute distribution of a particular simulation asset 106, say female traffic officer, may include short women, tall women, young women, old women, women wearing bright blue uniforms, women wearing faded blue uniforms, women with hats, women without hats, etc. Such simulations can enable a richer simulated dataset that has higher fidelity to the real world than other techniques where simulation assets 106 are either created manually or randomly from a limited collection of simulation assets. Rule-based asset creation module 120 may enable faster execution by simulator 100 with higher quality of generated data than with the other techniques mentioned above, thus improving performance of simulator 100.

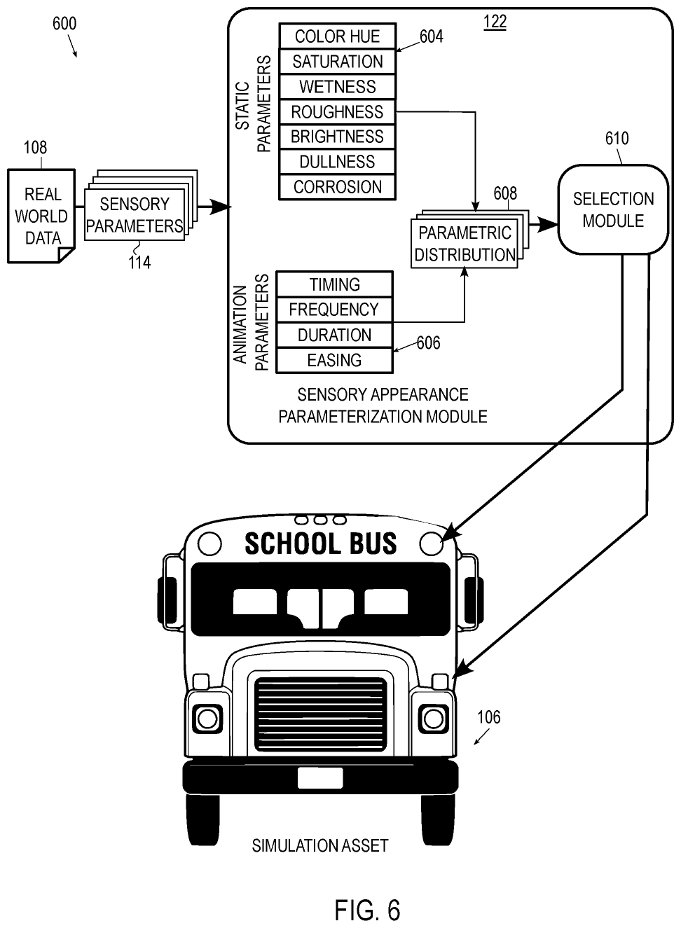

FIG. 6 illustrates a simplified block diagram of various features in an example computer implemented system for machine learning for AVs using parameterizable appearance features, according to some examples of the present disclosure. Real-world data 108 comprising appearance parameters 114 may be input into appearance parameterization module 122. Appearance parameters 114 include output from sensors of AV 102. Appearance parameters 114 may include data from cameras, LiDARs, radars, etc. and may comprise visual appearance attributes and other invisible attributes, for example, as sensed by radars. Appearance parameterization module 122 may separate various static parameters 604 and animation parameters 606 from appearance parameters 114 into corresponding parametric distributions 608. Static parameters 604 may include, by way of examples and not limitations, color hue, color saturation, degree of wetness, surface roughness, brightness, dullness, corrosion, etc. Animation parameters 606 may include timing, frequency, duration, easing, etc. In various examples, appearance parameters 114 may include various images and videos of simulation assets 106, from which static parameters 604 and animation parameters 606 may be extracted.

Consider, by way of example and not as a limitation, one of simulation assets 106 comprising a yellow school bus. A particular school bus may be old, with bleached yellow paint, a layer of dust covering its front lights, its red lights flashing erratically with varying frequency. Another school bus may be brand new, with bright yellow paint, clean, its red lights flashing according to factory specifications. These two different school buses will be perceived differently by the sensors of AV 102. However, both these school buses may be interpreted as such by the control stack of AV 102 to enable appropriate response by AV 102 to the flashing red lights (i.e., AV 102 may stop when the red lights are flashing, but not stop when the red lights are not flashing). The control stack of AV 102 comprises software modules executing on hardware components to control and/or otherwise influence motion and other behavior of AV 102.

To this end, parametric distribution 608 may comprise collated actualizations of a particular sensory appearance, for example, the brightness of the yellow color of the school bus. Appearance parameterization module 122 may parameterize the brightness levels into parametric distribution 608, which may tag images of different brightness levels with values from 1 to 10, for example, with 1 being dullest and 10 being brightest. Other such parameterizations are also possible and included within the broad scope of the disclosure herein. Each parametric distribution 608 for a separate static parameter 604 or animation parameter 606 may thus include discrete values of real-world data 108, as also the frequency of their appearance, range and other statistical attributes. In some examples, appearance parameters 114 may include an “ideal” value and a distribution type (e.g., normal, binomial, Poisson, exponential, etc.). The “ideal” value may be factory settings, for example, including nominal tolerances. In other examples, appearance parameters 114 may include data points corresponding to real-world values such as, but not limited to, factory and/or supplier fabrication tolerances, lens oxidation, color-fading, color bleaching, pitting, or illuminant (e.g., bulb) decay, and other such measurable parameters as measured by an appropriate instrument. All such types of data collections and distributions are included within the broad scope of the disclosure herein.

Selection module 610 may select a particular value from parametric distribution 608 for a particular one of static parameter 604 or animation parameter 606 for generating simulation asset 106 comprising the school bus. The selection may be random in some examples; in other examples, the selection may be based on instructions (e.g., instructions to select brightness level of 8, or instructions to generate old school bus, which may translate to brightness level of 2, and so on); in yet other examples, the selection may be based on a result of Monte Carlo simulations. In examples where Monte Carlo simulations are used, multiple parameter values may be assigned to static parameters 604 and animation parameters 606 from parametric distributions 608 to achieve multiple results and then the results are averaged to obtain a resultant sensory appearance for simulation asset 106. simulation asset 106 comprising the school bus may be generated thus based on various levels of each static parameter 604 and/or animation parameter 606. The resulting school bus may have close fidelity to real-world school buses, although there may not be an exact replica in the real world. Thus, the simulated data can enable generating additional scenarios for testing AV 102, filling in gaps in real-world data 108.

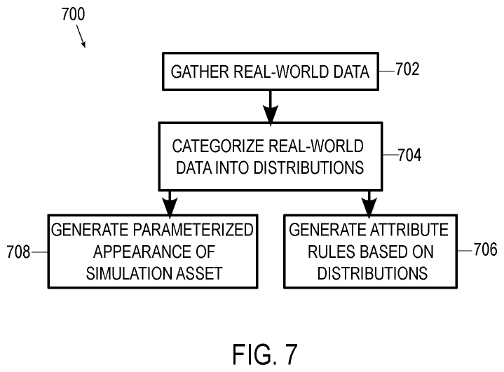

FIG. 7 illustrates a simplified flow diagram illustrating various operations 700 that may be associated with an example computer implemented system for machine learning for AVs using parameterizable attributes and appearance features, according to some examples of the present disclosure. At 702, real-world data 108 may be gathered by simulator 100. At 704, appropriate modules in scene creation module 116 may categorize real-world data 108 into distributions. For example, rule-based asset creation module 120 may categorize real-world data 108 into various assets having respective distributions; in another example, appearance parameterization module 122 may categorize real-world data 108 into various parametric distributions 608 as described in reference to FIG. 6. At 706, rule-based asset creation module 120 may generate rules based on the distributions. For example, attribute rule module 502 of rule-based asset creation module 120 may generate rules for various attribute sets for simulation asset 106 as described in reference to FIG. 5. At 708, a parameterized appearance of simulation asset 106 may be generated by selection module 610 of appearance parameterization module 122.

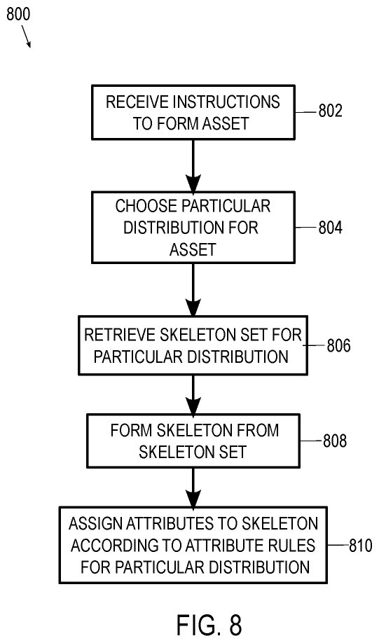

FIG. 8 illustrates a simplified flow diagram illustrating various operations 800 that may be associated with an example computer implemented system for machine learning for AVs using parameterizable skeletons and attributes, according to some examples of the present disclosure. At 802, instructions may be received at scene creation module 116 to form an asset (e.g., female traffic officer in City A). At 804, a particular distribution for the asset may be chosen (e.g., females in City A). At 806, skeleton set 210 for the particular distribution may be retrieved from skeleton database 212. At 808, simulated skeleton 214 for the asset may be formed as described in reference to the previous figures, for example, using scaling factors 304 according to skeleton set 210. At 810, attributes may be selected and assigned to simulated skeleton 214 according to attribute rules for the asset in the distribution (e.g., City A police uniform, female mesh, etc.).

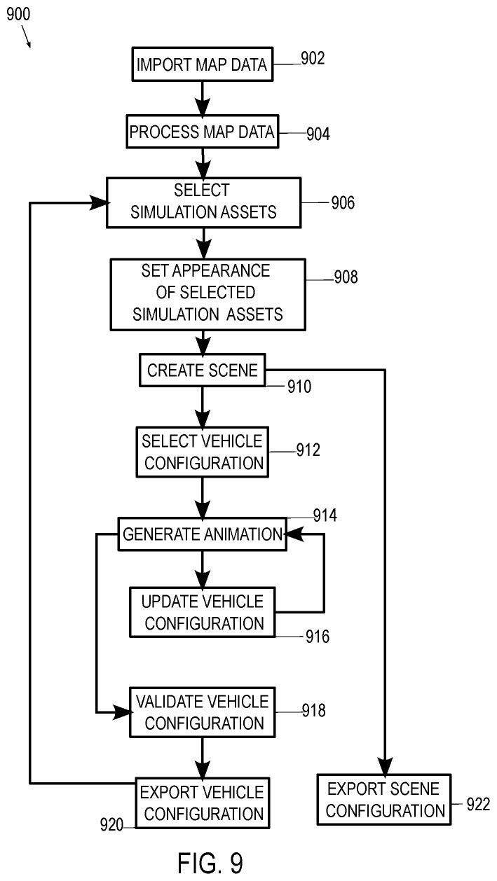

FIG. 9 illustrates a simplified flow diagram illustrating various operations 900 that may be associated with an example computer implemented system for machine learning for AVs using parameterizable skeletons, attributes, and appearance features, according to some examples of the present disclosure. At 902, map data associated with location of scene 104 to be simulated may be imported into simulator 100. At 904, the imported map data may be analyzed, for example, to determine associated simulation assets 106 such as buildings, trees, streetlights, etc. to be generated. At 906, simulation assets 106 for scene 104 may be chosen. At 908, appearance of selected simulation assets 106 may be set. At 910 scene 104 may be created. At 912, a vehicle configuration for AV 102 may be selected. The vehicle configuration may include settings of camera, LiDAR, gear, brake, lights, wipers, control stack, etc. At 914, the animation of an event may be created by simulator 100. In the animation AV 102 may be maneuvered around simulation assets 106 according to the vehicle configuration selected. In some examples, a video rendering of the simulation may be made available. In some other examples, a video rendering of the simulation may not be made available, and instead, the reaction of AV 102 may be captured as a series of messages and/or states of various sensors and systems in AV 102. The reaction of AV 102 to simulation assets 106 may be determined from the simulation. The reaction may be the behavior of sensors to simulation assets 106, for example, the image captured by cameras, or the amount of reflected light captured by LiDAR, or the determination by the control stack of AV 102 to sensor readings in the presence of simulation assets 106.

In some examples, the vehicle configuration includes settings of sensors in AV 102; simulating the maneuvering of AV 102 may comprise simulating a perception of simulation assets 106 by the sensors according to the settings, the reaction of AV 102 being the movement of AV 102 in response to the perception by the sensors. In some other examples, the vehicle configuration includes settings of a control stack of AV 102; simulating the maneuvering of AV 102 may comprise simulating control messages by the control stack according to the settings before AV 102 comes in the presence of simulation assets 106, the reaction of AV 102 being the movement of AV 102 in response to the control messages by the control stack.

At 916, the vehicle configuration may be updated if the simulation shows that AV 102 did not react to simulation assets 106 as desired. Operations 914 may be repeated with the updated vehicle configuration. Operations 914 and 916 may be repeated any number of times until a desired vehicle reaction is obtained. The vehicle configuration for the desired reaction may be validated at 918, for example, against manufacturer specifications of sensors and systems, for example, to ensure that the vehicle configuration is feasible and practical. At 920, the validated vehicle configuration may be exported to an appropriate format for use in simulator 100. At 922, the scene configuration with attributes and appearance of simulation assets 106 may be exported to the appropriate format for use in simulator 100, which may then upload the vehicle configuration and settings of scene 104 to AV 102 suitably.

Operations 900 as described may be repeated any number of times for various configurations of scene 104. In some examples, a yellow school bus with flashing red lights may be simulated. In some other examples, a bystander crossing a street may be simulated. In some other examples, traffic intersections managed by traffic officers may be simulated. Various other conditions and events may be simulated based on particular needs. In some examples, the conditions and events simulated may be of a specific safety test. simulation asset 106 may be generated for each such simulation according to particular needs by scene creation module 116.

FIG. 10 illustrates an example of an AV management system 1000. One of ordinary skill in the art will understand that, for the AV management system 1000 and any system discussed in the present disclosure, there can be additional or fewer components in similar or alternative configurations. The illustrations and examples provided in the present disclosure are for conciseness and clarity. Other examples may include different numbers and/or types of elements, but one of ordinary skill the art will appreciate that such variations do not depart from the scope of the present disclosure.

In this example, the AV management system 1000 includes an AV 102, a data center 1050, and a client computing device 1070. The AV 102, the data center 1050, and the client computing device 1070 can communicate with one another over one or more networks (not shown), such as a public network (e.g., the Internet, an Infrastructure as a Service (IaaS) network, a Platform as a Service (PaaS) network, a Software as a Service (SaaS) network, another Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

AV 102 can navigate about roadways without a human driver based on sensor signals generated by multiple sensor systems 1004, 1006, and 1008. The sensor systems 1004-1008 can include different types of sensors and can be arranged about the AV 102. For instance, the sensor systems 1004-1008 can comprise Inertial Measurement Units (IMUs), cameras (e.g., still image cameras, video cameras, etc.), light sensors (e.g., LiDAR systems, ambient light sensors, infrared sensors, etc.), RADAR systems, a Global Navigation Satellite System (GNSS) receiver, (e.g., Global Positioning System (GPS) receivers), audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 1004 can be a camera system, the sensor system 1006 can be a LiDAR system, and the sensor system 1008 can be a RADAR system. Other examples may include any other number and type of sensors.

AV 102 can also include several mechanical systems that can be used to maneuver or operate AV 102. For instance, the mechanical systems can include vehicle propulsion system 1030, braking system 1032, steering system 1034, safety system 1036, and cabin system 1038, among other systems. Vehicle propulsion system 1030 can include an electric motor, an internal combustion engine, or both. The braking system 1032 can include an engine brake, a wheel braking system (e.g., a disc braking system that utilizes brake pads), hydraulics, actuators, and/or any other suitable componentry configured to assist in decelerating AV 102. The steering system 1034 can include suitable componentry configured to control the direction of movement of the AV 102 during navigation. Safety system 1036 can include lights and signal indicators, a parking brake, airbags, and so forth. The cabin system 1038 can include cabin temperature control systems, in-cabin entertainment systems, and so forth. In some examples, the AV 102 may not include human driver actuators (e.g., steering wheel, handbrake, foot brake pedal, foot accelerator pedal, turn signal lever, window wipers, etc.) for controlling the AV 102. Instead, the cabin system 1038 can include one or more client interfaces (e.g., Graphical User Interfaces (GUIs), Voice User Interfaces (VUIs), etc.) for controlling certain aspects of the mechanical systems 1030-1038.

AV 102 can additionally include a local computing device 1010 that is in communication with the sensor systems 1004-1008, the mechanical systems 1030-1038, the data center 1050, and the client computing device 1070, among other systems. The local computing device 1010 can include one or more processors and memory, including instructions that can be executed by the one or more processors. The instructions can make up one or more software stacks or components responsible for controlling the AV 102; communicating with the data center 1050, the client computing device 1070, and other systems; receiving inputs from riders, passengers, and other entities within the AV's environment; logging metrics collected by the sensor systems 1004-1008; and so forth. In this example, the local computing device 1010 includes a perception stack 1012 a mapping and localization stack 1014, a planning stack 1016, a control stack 1018, a communications stack 1020, a High Definition (HD) geospatial database 1022, and an AV operational database 1024, among other stacks and systems.

Perception stack 1012 can enable the AV 102 to “see” (e.g., via cameras, LiDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 1004-1008, the mapping and localization stack 1014, the HD geospatial database 1022, other components of the AV, and other data sources (e.g., the data center 1050, the client computing device 1070, third-party data sources, etc.). The perception stack 1012 can detect and classify objects and determine their current and predicted locations, speeds, directions, and the like. In some examples, perception stack 1012 classifies a detected object according to the data from sensor systems 1004-1008. This classification is sent to downstream software components which can eventually result in a control stack generating hardware controls messages that affect the behavior of AV 102. In addition, the perception stack 1012 can determine the free space around the AV 102 (e.g., to maintain a safe distance from other objects, change lanes, park the AV, etc.). The perception stack 1012 can also identify environmental uncertainties, such as where to look for moving objects, flag areas that may be obscured or blocked from view, and so forth. In various examples, the behavior of perception stack 1012 may be trained using simulator 100 as described in previous figures.

Mapping and localization stack 1014 can determine the AV's position and orientation (pose) using different methods from multiple systems (e.g., GPS, IMUs, cameras, LiDAR, RADAR, ultrasonic sensors, the HD geospatial database 1022, etc.). For example, in some examples, the AV 102 can compare sensor data captured in real-time by the sensor systems 404-408 to data in the HD geospatial database 1022 to determine its precise (e.g., accurate to the order of a few centimeters or less) position and orientation. The AV 102 can focus its search based on sensor data from one or more first sensor systems (e.g., GPS) by matching sensor data from one or more second sensor systems (e.g., LiDAR). If the mapping and localization information from one system is unavailable, the AV 102 can use mapping and localization information from a redundant system and/or from remote data sources.

The planning stack 1016 can determine how to maneuver or operate the AV 102 safely and efficiently in its environment. For example, the planning stack 1016 can receive the location, speed, and direction of the AV 102, geospatial data, data regarding objects sharing the road with the AV 102 (e.g., pedestrians, bicycles, vehicles, ambulances, buses, cable cars, trains, traffic lights, lanes, road markings, etc.) or certain events occurring during a trip (e.g., an Emergency Vehicle (EMV) blaring a siren, intersections, occluded areas, street closures for construction or street repairs, Double-Parked Vehicles (DPVs), etc.), traffic rules and other safety standards or practices for the road, user input, and other relevant data for directing the AV 102 from one point to another. The planning stack 1016 can determine multiple sets of one or more mechanical operations that the AV 102 can perform (e.g., go straight at a specified speed or rate of acceleration, including maintaining the same speed or decelerating; power on the left blinker, decelerate if the AV is above a threshold range for turning, and turn left; power on the right blinker, accelerate if the AV is stopped or below the threshold range for turning, and turn right; decelerate until completely stopped and reverse; etc.), and select the best one to meet changing road conditions and events. If something unexpected happens, the planning stack 1016 can select from multiple backup plans to carry out. For example, while preparing to change lanes to turn right at an intersection, another vehicle may aggressively cut into the destination lane, making the lane change unsafe. The planning stack 1016 could have already determined an alternative plan for such an event, and upon its occurrence, help to direct the AV 102 to go around the block instead of blocking a current lane while waiting for an opening to change lanes. In various examples, the behavior of planning stack 1016 may be trained using simulator 100 as described in previous figures.

The control stack 1018 can manage the operation of the vehicle propulsion system 1030, the braking system 1032, the steering system 1034, the safety system 1036, and the cabin system 1038. The control stack 1018 can receive sensor signals from the sensor systems 1004-1008 as well as communicate with other stacks or components of the local computing device 1010 or a remote system (e.g., the data center 1050) to effectuate operation of the AV 102. For example, the control stack 1018 can implement the final path or actions from the multiple paths or actions provided by the planning stack 1016. This can involve turning the routes and decisions from the planning stack 1016 into commands for the actuators that control the AV's steering, throttle, brake, and drive unit. In various examples, the behavior of control stack 1018 may be trained using simulator 100 as described in previous figures.

The communication stack 1020 can transmit and receive signals between the various stacks and other components of the AV 102 and between the AV 102, the data center 1050, the client computing device 1070, and other remote systems. The communication stack 1020 can enable the local computing device 1010 to exchange information remotely over a network, such as through an antenna array or interface that can provide a metropolitan WI-FI® network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communication stack 420 can also facilitate local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 1022 can store HD maps and related data of the streets upon which the AV 102 travels. In some examples, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane or road centerline, lane boundaries, type of lane boundaries, etc.) and related attributes (e.g., direction of travel, speed limit, lane type, etc.). The lanes and boundaries layer can also include 3D attributes related to lanes (e.g., slope, elevation, curvature, etc.). The intersections layer can include geospatial information of intersections (e.g., crosswalks, stop lines, turning lane centerlines, and/or boundaries, etc.) and related attributes (e.g., permissive, protected/permissive, or protected only left turn lanes; permissive, protected/permissive, or protected only U-turn lanes; permissive or protected only right turn lanes; etc.). The traffic controls layer can include geospatial information of traffic signal lights, traffic signs, and other road objects and related attributes.

The AV operational database 1024 can store raw AV data generated by the sensor systems 404-408 and other components of the AV 102 and/or data received by the AV 102 from remote systems (e.g., the data center 1050, the client computing device 1070, etc.). In some examples, the raw AV data can include HD LiDAR point cloud data, image or video data, RADAR data, GPS data, and other sensor data that the data center 450 can use for creating or updating AV geospatial data.

The data center 1050 can be a private cloud (e.g., an enterprise network, a co-location provider network, etc.), a public cloud (e.g., an IaaS network, a PaaS network, a SaaS network, or other CSP network), a hybrid cloud, a multi-cloud, and so forth. The data center 1050 can include one or more computing devices remote to the local computing device 1010 for managing a fleet of AVs and AV-related services. For example, in addition to managing the AV 102, the data center 450 may also support a ridesharing service, a delivery service, a remote/roadside assistance service, street services (e.g., street mapping, street patrol, street cleaning, street metering, parking reservation, etc.), and the like.

The data center 1050 can send and receive various signals to and from the AV 102 and the client computing device 1070. These signals can include sensor data captured by the sensor systems 1004-1008, roadside assistance requests, software updates, ridesharing pick up and drop-off instructions, and so forth. In this example, the data center 1050 includes one or more of a data management platform 1052, an Artificial Intelligence/Machine Learning (AI/ML) platform 1054, a simulation platform 1056, a remote assistance platform 1058, a ridesharing platform 1060, and a map management platform 1062, among other systems.

Data management platform 1052 can be a “big data” system capable of receiving and transmitting data at high speeds (e.g., near real-time or real-time), processing a large variety of data, and storing large volumes of data (e.g., terabytes, petabytes, or more of data). The varieties of data can include data having different structures (e.g., structured, semistructured, unstructured, etc.), data of different types (e.g., sensor data, mechanical system data, ridesharing service data, map data, audio data, video data, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), or data having other heterogeneous characteristics. The various platforms and systems of the data center 1050 can access data stored by the data management platform 1052 to provide their respective services.

The AI/ML platform 1054 can provide the infrastructure for training and evaluating machine learning algorithms for operating the AV 102, the simulation platform 1056, the remote assistance platform 1058, the ridesharing platform 1060, the map management platform 1062, and other platforms and systems. Using the AI/ML platform 1054, data scientists can prepare data sets from the data management platform 1052; select, design, and train machine learning models; evaluate, refine, and deploy the models; maintain, monitor, and retrain the models; and so on.

The simulation platform 1056 can enable testing and validation of the algorithms, machine learning models, neural networks, and other development efforts for the AV 102, the remote assistance platform 1058, the ridesharing platform 1060, the map management platform 1062, and other platforms and systems. The simulation platform 1056 can replicate a variety of driving environments and/or reproduce real-world scenarios from data captured by the AV 102, including rendering geospatial information and road infrastructure (e.g., streets, lanes, crosswalks, traffic lights, stop signs, etc.) obtained from the map management platform 1062; modeling the behavior of other vehicles, bicycles, pedestrians, and other dynamic elements; simulating inclement weather conditions, different traffic scenarios; and so on. Various operations of simulation platform 1056 may be executed by simulator 100 as described in reference to the previous figures.

The remote assistance platform 1058 can generate and transmit instructions regarding the operation of the AV 102. For example, in response to an output of the AI/ML platform 1054 or other system of the data center 1050, the remote assistance platform 1058 can prepare instructions for one or more stacks or other components of the AV 102.

The ridesharing platform 1060 can interact with a customer of a ridesharing service via a ridesharing application 1072 executing on the client computing device 4100. The client computing device 1070 can be any type of computing system, including a server, desktop computer, laptop, tablet, smartphone, smart wearable device (e.g., smart watch; smart eyeglasses or other Head-Mounted Display (HMD); smart ear pods or other smart in-ear, on-ear, or over-ear device; etc.), gaming system, or other general-purpose computing device for accessing the ridesharing application 1072. The client computing device 1070 can be a customer's mobile computing device or a computing device integrated with the AV 102 (e.g., the local computing device 1010). The ridesharing platform 1060 can receive requests to be picked up or dropped off from the ridesharing application 1072 and dispatch the AV 102 for the trip.

Map management platform 1062 can provide a set of tools for the manipulation and management of geographic and spatial (geospatial) and related attribute data. The data management platform 1052 can receive LiDAR point cloud data, image data (e.g., still image, video, etc.), RADAR data, GPS data, and other sensor data (e.g., raw data) from one or more AVs 102, Unmanned Aerial Vehicles (UAVs), satellites, third-party mapping services, and other sources of geospatially referenced data. The raw data can be processed, and map management platform 1062 can render base representations (e.g., tiles (2D), bounding volumes (3D), etc.) of the AV geospatial data to enable users to view, query, label, edit, and otherwise interact with the data. Map management platform 1062 can manage workflows and tasks for operating on the AV geospatial data. Map management platform 1062 can control access to the AV geospatial data, including granting or limiting access to the AV geospatial data based on user-based, role-based, group-based, task-based, and other attribute-based access control mechanisms. Map management platform 1062 can provide version control for the AV geospatial data, such as to track specific changes that (human or machine) map editors have made to the data and to revert changes when necessary. Map management platform 1062 can administer release management of the AV geospatial data, including distributing suitable iterations of the data to different users, computing devices, AVs, and other consumers of HD maps. Map management platform 1062 can provide analytics regarding the AV geospatial data and related data, such as to generate insights relating to the throughput and quality of mapping tasks.

In some examples, the map viewing services of map management platform 1062 can be modularized and deployed as part of one or more of the platforms and systems of the data center 1050. For example, the AI/ML platform 1054 may incorporate the map viewing services for visualizing the effectiveness of various object detection or object classification models, the simulation platform 1056 may incorporate the map viewing services for recreating and visualizing certain driving scenarios, the remote assistance platform 1058 may incorporate the map viewing services for replaying traffic incidents to facilitate and coordinate aid, the ridesharing platform 1060 may incorporate the map viewing services into the client application 1072 to enable passengers to view the AV 102 in transit en route to a pick up or drop-off location, and so on.

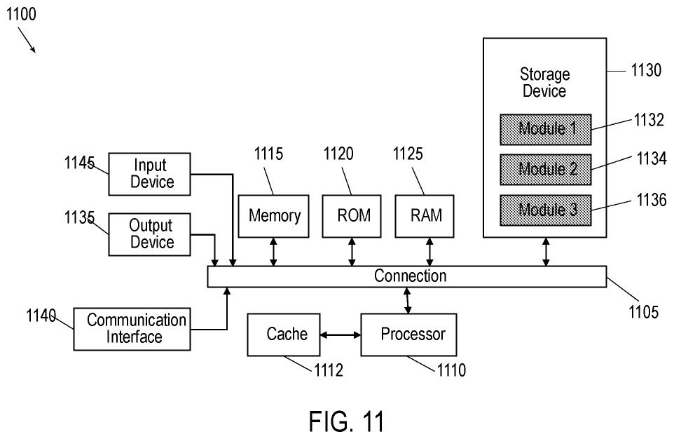

FIG. 11 illustrates an example processor-based system with which some aspects of the subject technology may be implemented. For example, processor-based system 1100 may be any computing device making up, or any component thereof in which the components of the system are in communication with each other using connection 1105. Connection 1105 may be a physical connection via a bus, or a direct connection into processor 1110, such as in a chipset architecture. Connection 1105 may also be a virtual connection, networked connection, or logical connection.

In some examples, computing system 1100 is a distributed system in which the functions described in this disclosure may be distributed within a datacenter, multiple data centers, a peer network, etc. In some examples, one or more of the described system components represents many such components each performing some or all of the function for which the component is described. In some examples, the components may be physical or virtual devices.

Example system 1100 includes at least one processing unit (Central Processing Unit (CPU) or processor) 1110 and connection 1105 that couples various system components including system memory 1115, such as Read Only Memory (ROM) 1120 and Random-Access Memory (RAM) 1125 to processor 1110. Computing system 1100 may include a cache of high-speed memory 1112 connected directly with, in close proximity to, or integrated as part of processor 1110.

Processor 1110 may include any general-purpose processor and a hardware service or software service, such as modules 1132-1136 stored in storage device 1130, configured to control processor 1110 as well as a special purpose processor where software instructions are incorporated into the actual processor design. The modules 1132-1136 may include, by way of examples and not as limitations, distribution-based skeleton selection module 118, rule-based asset creation module 120 and appearance parameterization module 122, which may include various instructions for operations as discussed herein. Processor 1110 may essentially be a completely self-contained computing system, containing multiple cores or processors, a bus, memory controller, cache, etc. A multi-core processor may be symmetric or asymmetric.

To enable user interaction, computing system 1100 includes an input device 1145, which may represent any number of input mechanisms, such as a microphone for speech, a touch-sensitive screen for gesture or graphical input, keyboard, mouse, motion input, speech, etc. Computing system 1100 may also include output device 1135, which may be one or more of a number of output mechanisms known to those of skill in the art. In some instances, multimodal systems may enable a user to provide multiple types of input/output to communicate with computing system 1100. Computing system 1100 may include communications interface 1140, which may generally govern and manage the user input and system output. The communication interface may perform or facilitate receipt and/or transmission wired or wireless communications via wired and/or wireless transceivers, including those making use of an audio jack/plug, a microphone jack/plug, a USB port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a Radio-Frequency Identification (RFID) wireless signal transfer, Near-Field Communications (NFC) wireless signal transfer, Dedicated Short Range Communication (DSRC) wireless signal transfer, 802.11 Wi-Fi® wireless signal transfer, WLAN signal transfer, Visible Light Communication (VLC) signal transfer, Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad hoc network signal transfer, radio wave signal transfer, microwave signal transfer, infrared signal transfer, visible light signal transfer signal transfer, ultraviolet light signal transfer, wireless signal transfer along the electromagnetic spectrum, or some combination thereof.

Communication interface 1140 may also include one or more GNSS receivers or transceivers that are used to determine a location of the computing system 1100 based on receipt of one or more signals from one or more satellites associated with one or more GNSS systems. GNSS systems include, but are not limited to, the US-based GPS, the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 1130 may be a non-volatile and/or non-transitory and/or computer-readable memory device and may be a hard disk or other types of computer-readable media which may store data that are accessible by a computer, such as magnetic cassettes, flash memory cards, solid-state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a Compact Disc (CD) Read Only Memory (CD-ROM) optical disc, a rewritable CD optical disc, a Digital Video Disk (DVD) optical disc, a Blu-ray Disc (BD) optical disc, a holographic optical disk, another optical medium, a Secure Digital (SD) card, a micro SD (microSD) card, a Memory Stick® card, a smartcard chip, a EMV chip, a Subscriber Identity Module (SIM) card, a mini/micro/nano/pico SIM card, another Integrated Circuit (IC) chip/card, RAM, Atatic RAM (SRAM), Dynamic RAM (DRAM), ROM, Programmable ROM (PROM), Erasable PROM (EPROM), Electrically Erasable PROM (EEPROM), flash EPROM (FLASHEPROM), cache memory (L1/L2/L3/L4/L5/L #), Resistive RAM (RRAM/ReRAM), Phase Change Memory (PCM), Spin Transfer Torque RAM (STT-RAM), another memory chip or cartridge, and/or a combination thereof.

Storage device 1130 may include software services, servers, services, etc., that when the code that defines such software is executed by the processor 1110, it causes the system 1100 to perform a function. In some examples, a hardware service that performs a particular function may include the software component stored in a computer-readable medium in connection with the necessary hardware components, such as processor 1110, connection 1105, output device 1135, etc., to carry out the function.

Examples within the scope of the present disclosure may also include tangible and/or non-transitory computer-readable storage media or devices for carrying or having computer-executable instructions or data structures stored thereon. Such tangible computer-readable storage devices may be any available device that may be accessed by a general-purpose or special purpose computer, including the functional design of any special purpose processor as described above. By way of example, and not limitation, such tangible computer-readable devices may include RAM, ROM, EEPROM, CD-ROM or other optical disk storage, magnetic disk storage or other magnetic storage devices, or any other device which may be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other examples of the disclosure may be practiced in network computing environments with many types of computer system configurations, including personal computers, hand-held devices, multi-processor systems, microprocessor-based or programmable consumer electronics, network Personal Computers (PCs), minicomputers, mainframe computers, and the like. Examples may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

As described herein, one aspect of the present technology is the gathering and use of data available from various sources to improve quality and experience. The present disclosure contemplates that in some instances, this gathered data may include personal information. The present disclosure contemplates that the entities involved with such personal information respect and value privacy policies and practices.

### Selected Examples

Example 1 provides a computer-implemented system, comprising: one or more non-transitory computer-readable media storing instructions, when executed by one or more processing units, cause the one or more processing units to perform operations comprising: retrieving real-world data comprising skeleton attributes of various skeletons, each skeleton comprising a digital hierarchical framework of bones; receiving instructions to generate a simulated skeleton for a scene in a simulation; generating the simulated skeleton according to the scene based on the skeleton attributes, the simulated skeleton comprising the digital hierarchical framework of bones of a generic skeleton modified by scaling factors according to the scene; building a simulation asset using the simulated skeleton; and determining a reaction of a vehicle to the simulation asset in the scene simulated, the reaction of the vehicle being a function of a configuration of the vehicle.
Example 2 provides the computer-implemented system of example 1, the operations further comprising: in response to the reaction, updating the configuration; repeating the determining the reaction and the updating the configuration until a desired reaction is obtained; and exporting a final updated configuration corresponding to the desired reaction to a physical vehicle.
Example 3 provides the computer-implemented system of example 2, wherein: the configuration includes settings of sensors in the vehicle, determining the reaction is by simulating sensing of the simulation asset by the sensors according to the settings, and the reaction of the vehicle comprises, in response to the sensing by the sensors, at least one of: (i) movement of the vehicle or (ii) classification of the simulation asset by a control stack of the vehicle.
Example 4 provides the computer-implemented system of any one of examples 2-3, wherein: the configuration includes settings of a control stack of the vehicle, the determining is by generating control messages by the control stack according to the settings when sensors of the vehicle perceive the simulation asset, and the reaction of the vehicle comprises movement of the vehicle in response to the control messages by the control stack.
Example 5 provides the computer-implemented system of any one of examples 1-4, wherein: generating the simulated skeleton comprises generating skeleton sets from the skeleton attributes, each skeleton set comprises bones from a subset of the various skeletons, the subset of various skeletons is selected according to a preconfigured rule, and different skeleton sets are associated with correspondingly different preconfigured rules.
Example 6 provides the computer-implemented system of example 5, wherein the instructions comprise settings of the scene, the settings indicating one of several preconfigured rules.
Example 7 provides the computer-implemented system of example 6, wherein generating the simulated skeleton further comprises choosing a corresponding one of skeleton sets according to the one of the preconfigured rules indicated in the settings.
Example 8 provides the computer-implemented system of example 7, wherein: generating the simulated skeleton further comprises selecting distinct scaling factors for each bone in the skeleton set chosen, and modifying the bones of the generic skeleton by the respective scaling factors selected for the bones.
Example 9 provides the computer-implemented system of any one of examples 7-8, wherein: different bones in each skeleton set are categorized into corresponding distributions, and an individual scaling factor is selected from the respective distribution associated with the corresponding bone.
Example 10 provides the computer-implemented system of any one of examples 7-9, wherein modifying the bones comprises: multiplying a dimension of an individual bone by the corresponding scaling factor to generate a final dimension of the individual bone in the simulated skeleton; and repeating the multiplying for each bone in the generic skeleton.
Example 11 provides the computer-implemented system of any one of examples 1-10, wherein the skeleton attributes comprise dimension and range of motion of each bone in the various skeletons.
Example 12 provides a method, comprising: retrieving, by a computer-implemented system, real-world data comprising skeleton attributes of various skeletons, each skeleton comprising a digital hierarchical framework of bones, the skeleton attributes comprising at least a dimension of each bone; generating, by the computer-implemented system, skeleton sets from the skeleton attributes, bones in each skeleton set being categorized into respective distributions; and saving, by the computer-implemented system, the skeleton sets in a skeleton data lake.
Example 13 provides the method of example 12, wherein the skeleton sets are stored as tagged data in the skeleton data-lake.
Example 14 provides the method of example 12, wherein the skeleton sets are stored as structured datasets in the skeleton data-lake.
Example 15 provides the method of any one of examples 12-14, wherein: each skeleton set comprises bones from a different subset of the various skeletons, and each subset of various skeletons is selected according to a corresponding preconfigured rule.
Example 16 provides the method of any one of examples 12-15, further comprising: receiving, by the computer-implemented system, instructions to generate a simulated skeleton for a scene in a simulation; selecting, by the computer-implemented system, an individual one of the skeleton sets from the skeleton data lake according to the scene; selecting, by the computer-implemented system, scaling factors for generic bones in a generic skeleton, each scaling factor being selected from the respective distribution for the corresponding bone in the individual one of the skeleton sets; generating, by the computer-implemented system, the simulated skeleton according to the scene based on the skeleton attributes, the simulated skeleton comprising the generic skeleton modified by the scaling factors; and building, by a computer-implemented system, an simulation asset using the simulated skeleton.
Example 17 provides the method of example 16, wherein: a first simulated skeleton is generated from a particular one of the skeleton sets, a second simulated skeleton is generated from the particular one of the skeleton sets, and the first simulated skeleton is different from the second simulated skeleton according to the respective scaling factors used to generate the corresponding first simulated skeleton and the second simulated skeleton.
Example 18 provides the method of example 16, wherein: a first simulated skeleton is generated from a first skeleton set, a second simulated skeleton is generated from a second skeleton set, and the first simulated skeleton is different from the second simulated skeleton according to the difference in distributions of the bones of the first skeleton set and the second skeleton set.
Example 19 provides the method of any one of examples 16-18, wherein: the generic bones in the generic skeleton have respective preconfigured dimensions, each distribution in the individual one of the skeleton sets comprises a minimum value and a maximum value of the dimension of the corresponding bone, and the scaling factor for any one generic bone is a random selection between the minimum value and the maximum value in the distribution of the corresponding bone to the preconfigured dimension of the generic bone.
Example 20 provides the method of any one of examples 16-19, wherein the skeleton attributes further comprise ranges of motion of the bones in the various skeletons.
Example 21 provides the method of example 20, wherein: the generic bones in the generic skeleton have respective preconfigured ranges of motion, each distribution in the individual one of the skeleton sets comprises a minimum value and a maximum value of the range of motion of the corresponding bone, and the scaling factor for any one generic bone is a random selection between the minimum value and the maximum value in the distribution of the corresponding bone to the preconfigured range of motion of the generic bone.
Example 22 provides a method, comprising: generating, by a computer-implemented system, skeleton sets including distributions of bones from various skeletons; selecting, by the computer-implemented system, a particular one of the skeleton sets; selecting, by the computer-implemented system, scaling factors for each bone from the corresponding distributions in the particular one of the skeleton sets; and modifying, by the computer-implemented system, a generic skeleton by the scaling factors, wherein: the skeletons comprise digital hierarchical frameworks of the bones, each bone in any one skeleton is identified by a matching identifier, corresponding bones in separate skeletons share the matching identifier, the bones from the various skeletons are grouped into the respective distributions according to the corresponding matching identifiers.
Example 23 provides the method of example 22, wherein the scaling factors are randomly selected from the corresponding distributions.
Example 24 provides the method of any one of examples 22-23, wherein the scaling factors are different for at least two bones having different identifiers.
Example 25 provides the method of any one of examples 22-24, wherein the particular one of the skeleton sets is selected according to scene settings in a simulator.
Example 26 provides the method of any one of examples 22-25, wherein modifying the generic skeleton comprises scaling each bone in the generic skeleton by the corresponding scaling factor.
Example 27 provides a computer-implemented system, comprising: one or more non-transitory computer-readable media storing instructions, when executed by one or more processing units, cause the one or more processing units to perform operations comprising: retrieving real-world data comprising attributes of objects and people in a region; deriving attribute rules for the attributes; receiving instructions to generate an simulation asset for a scene in a simulation, the simulation asset having a subset of the attributes; generating the simulation asset, the simulation asset having characteristics according to attribute rules corresponding to the subset of the attributes; and determining a reaction of a vehicle to the simulation asset in the scene simulated, the reaction of the vehicle being a function of a configuration of the vehicle.
Example 28 provides the computer-implemented system of example 27, the operations further comprising: in response to the reaction, updating the configuration; repeating the determining the reaction and the updating the configuration until a desired reaction is obtained; and exporting a final updated configuration corresponding to the desired reaction to a physical vehicle.
Example 29 provides the computer-implemented system of example 28, wherein: the configuration includes settings of sensors in the vehicle, the determining is by simulating a sensing of the simulation asset by the sensors according to the settings, and the reaction of the vehicle comprises, in response to the sensing by the sensors, at least one of: (i) movement of the vehicle or (ii) classification of the simulation asset by a control stack of the vehicle.
Example 30 provides the computer-implemented system of any one of examples 28-29, wherein: the configuration includes settings of a control stack of the vehicle, the determining is by simulating control messages by the control stack according to the settings when sensors of the vehicle perceive the simulation asset, and the reaction of the vehicle comprises movement of the vehicle in response to the control messages by the control stack.
Example 31 provides the computer-implemented system of any one of examples 27-30, wherein each simulation asset is associated with at least one distinct attribute distribution.
Example 32 provides the computer-implemented system of any one of examples 27-31, wherein: the simulation asset is a first simulation asset, the subset of the asset attributes is a first subset, and the operation further comprise: receiving instructions to generate a second simulation asset for the scene, the second simulation asset having a second subset of the asset attributes; and generating the second simulation asset, the second simulation asset having characteristics according to attribute rules corresponding to the second subset of the asset attributes.
Example 33 provides the computer-implemented system of any one of examples 27-32, wherein: the instructions to generate the simulation asset are according to settings of the scene, the settings indicate one or more attribute distributions, the subset of the asset attributes is associated with a particular one of the attribute distributions, and the operations further comprise: identifying the particular one of the attribute distributions indicated by the settings; identifying the subset of asset attributes associated with the particular one of the attribute distributions; and generating simulation assets having characteristics corresponding to the subset of the asset attributes according to the attribute rules.
Example 34 provides the computer-implemented system of example 33, wherein the simulation assets are assigned to skeletons selected according to the settings of the scene.
Example 35 provides the computer-implemented system of any one of examples 33-34, wherein different attribute sets for separate ones of the attribute distributions are generated according to the attribute rules.
Example 36 provides the computer-implemented system of example 35, wherein the asset attributes of the simulation assets are selected from the attribute sets.
Example 37 provides the computer-implemented system of any one of examples 27-36, wherein the asset attributes comprise at least: color, type, accessories, movement and pose, and the corresponding asset attributes comprise at least: color, mesh, attachment, animation and pose.
Example 38 provides a method, comprising: retrieving, by a computer-implemented system, real-world data comprising asset attributes of objects and people in a region; categorizing, by the computer-implemented system, the asset attributes of the objects and people into a plurality of attribute distributions; deriving, by the computer-implemented system, attribute rules within each attribute distribution for asset attributes based on the asset attributes; receiving, by the computer-implemented system, instructions to generate a character according to a configuration of a scene; selecting, by the computer-implemented system, one of the attribute distributions according to the configuration; selecting, by the computer-implemented system, simulation assets associated with the selected attribute distribution; and assigning, by the computer-implemented system, asset attributes to the selected simulation assets according to the attribute rules derived for the selected attribute distribution.
Example 39 provides the method of example 38, wherein the asset attributes comprise color, mesh, attachment, animation and pose.
Example 40 provides the method of any one of examples 38-39, wherein the asset attributes are grouped into attribute sets by the attribute rules.
Example 41 provides the method of example 40, wherein the grouping into attribute sets is based on a frequency of appearance of the asset attributes of the objects and people in the attribute distribution.
Example 42 provides the method of any one of examples 40-41, wherein assigning the asset attributes comprises random selections from the attribute sets.
Example 43 provides the method of any one of examples 40-42, wherein: a first simulation asset selected from the selected attribute distribution is assigned a first plurality of asset attributes, a second simulation asset selected from the selected attribute distribution is assigned a second plurality of asset attributes, and the first plurality of asset attributes is different from the second plurality of asset attributes.
Example 44 provides the method of any one of examples 38-43, wherein different attribute distributions are associated with correspondingly different attribute rules.
Example 45 provides the method of any one of examples 38-44, wherein the attribute rules for a specific asset attribute in a particular attribute distribution specify various possibilities for the specific asset attribute within the particular attribute distribution.
Example 46 provides the method of any one of examples 38-45, further comprising receiving, by the computer-implemented system, instructions to generate another character, wherein: the selected attribute distribution is a first attribute distribution, the another character is associated with a second attribute distribution, a first simulation asset selected from the first attribute distribution is assigned a first plurality of asset attributes, a second simulation asset selected from the second attribute distribution is assigned a second plurality of asset attributes, and the first plurality of asset attributes is different from the second plurality of asset attributes.
Example 47 provides a computer-implemented system, comprising: one or more non-transitory computer-readable media storing instructions, when executed by one or more processing units, cause the one or more processing units to perform operations comprising: retrieving real-world data comprising appearances of objects in an operational design domain; receiving instructions to generate an simulation asset comprising an individual one of the objects according to a configuration of a scene; generating the simulation asset having a parameterized appearance representing one of various possible appearances of the individual one of the objects in the operational design domain; and determining a reaction of a vehicle to the simulation asset in the scene simulated, the reaction of the vehicle being a function of a configuration of the vehicle.
Example 48 provides the computer-implemented system of example 47, the operations further comprising: in response to the reaction, updating the configuration; repeating the determining the reaction and the updating the configuration until a desired reaction is obtained; and exporting a final updated configuration corresponding to the desired reaction to a physical vehicle.
Example 49 provides the computer-implemented system of example 48, wherein: the configuration includes settings of sensors in the vehicle, the determining is by simulating a sensing of the simulation asset by the sensors according to the settings, and the reaction of the vehicle comprises, in response to the sensing by the sensors, at least one of: (i) movement of the vehicle or (ii) classification of the simulation asset by a control stack of the vehicle.
Example 50 provides the computer-implemented system of any one of examples 48-49, wherein: the configuration includes settings of a control stack of the vehicle, the determining is by simulating control messages by the control stack according to the settings when sensors of the vehicle perceive the simulation asset, and the reaction of the vehicle comprises movement of the vehicle in response to the control messages by the control stack.
Example 51 provides the computer-implemented system of any one of examples 47-50, wherein the operational design domain comprises various specific operating conditions in which the vehicle is configured to operate.
Example 52 provides the computer-implemented system of any one of examples 47-51, wherein the operations further comprise categorizing the appearances into corresponding parametric distributions.
Example 53 provides the computer-implemented system of example 52, wherein the parameterized appearance of the simulation asset comprises a random selection from the respective parametric distribution.
Example 54 provides the computer-implemented system of example 52, wherein the parameterized appearance of the simulation asset comprises a particular selection from the respective parametric distribution, the particular selection being based on the instructions.
Example 55 provides the computer-implemented system of example 52, wherein the parameterized appearance of the simulation asset is a result of one or more Monte Carlo simulations using various randomly selected parameters from different parametric distributions.
Example 56 provides the computer-implemented system of any one of examples 47-55, wherein the appearances comprise at least one selection from a set comprising static parameters, including color hue, color saturation, color brightness, color dullness, wetness of a surface, surface roughness, and extent of visible corrosion.
Example 57 provides the computer-implemented system of any one of examples 47-56, wherein the appearances comprise at least one selection from a set comprising animation parameters, including timing, frequency, duration and easing.
Example 58 provides a method, comprising: retrieving, by a computer-implemented system, real-world data comprising appearances of objects in an operational design domain; categorizing, by the computer-implemented system, the appearances into parametric distributions; receiving, by the computer-implemented system, instructions to generate an simulation asset comprising a representation of an individual one of the objects according to a configuration of a scene; and generating, by the computer-implemented system, a parameterized appearance of the individual one of the objects, wherein: the parameterized appearance represents one of various possible appearances of the individual one of the objects in the operational design domain, and the parameterized appearance is a random selection of parameters in the corresponding distribution associated with the respective appearance.
Example 59 provides the method of example 58, wherein generating the parameterized appearance comprises: separating the appearance into static parameters and animation parameters; categorizing individual ones of the static parameters and the animation parameters into corresponding parametric distributions; and selecting particular values of individual ones of the static parameters and the animation parameters from the corresponding parametric distributions, wherein the combination of the particular values comprises the parameterized appearance.
Example 60 provides the method of example 59, wherein the particular values are selected based on Monte Carlo simulations.
Example 61 provides the method of example 59, wherein the particular values are selected randomly.
Example 62 provides the method of example 59, wherein the particular values are selected according to the instructions.
Example 63 provides the method of any one of examples 59-62, wherein: the static parameters comprise color hue, color saturation, color brightness, color dullness, wetness of a surface, surface roughness, and extent of visible corrosion, and the animation parameters include timing, frequency, duration and easing.

The various examples described above are provided by way of illustration only and should not be construed to limit the scope of the disclosure. For example, the principles herein apply equally to optimization as well as general improvements. Various modifications and changes may be made to the principles described herein without following the example examples and applications illustrated and described herein, and without departing from the spirit and scope of the disclosure. Claim language reciting “at least one of” a set indicates that one member of the set or multiple members of the set satisfy the claim.

What is claimed is:

1. A computer-implemented system, comprising:
one or more non-transitory computer-readable media storing instructions, when executed by one or more processing units, cause the one or more processing units to perform operations comprising:
retrieving real-world data comprising skeleton attributes of various skeletons, each skeleton comprising a digital hierarchical framework of bones;
receiving instructions to generate a simulated skeleton for a scene in a simulation;
generating the simulated skeleton according to the scene based on the skeleton attributes, the simulated skeleton comprising the digital hierarchical framework of bones of a generic skeleton modified by scaling factors according to the scene;
building a simulation asset using the simulated skeleton; and
determining a reaction of a vehicle to the simulation asset in the scene simulated, the reaction of the vehicle being a function of a configuration of the vehicle.

2. The computer-implemented system of claim 1, the operations further comprising:
in response to the reaction, updating the configuration;
repeating determining the reaction and updating the configuration until a desired reaction is obtained; and
exporting a final updated configuration corresponding to the desired reaction to a physical vehicle.

3. The computer-implemented system of claim 2, wherein:
the configuration includes settings of sensors in the vehicle,
determining the reaction is by simulating sensing of the simulation asset by the sensors according to the settings, and
the reaction of the vehicle comprises, in response to the sensing by the sensors, at least one of: (i) movement of the vehicle or (ii) classification of the simulation asset by a perception stack of the vehicle.

4. The computer-implemented system of claim 2, wherein:
the configuration includes settings of a control stack of the vehicle,
the determining is by generating control messages by the control stack according to the settings when sensors of the vehicle perceive the simulation asset, and
the reaction of the vehicle comprises movement of the vehicle in response to the control messages by the control stack.

5. The computer-implemented system of claim 1, wherein:
generating the simulated skeleton comprises generating skeleton sets from the skeleton attributes,
each skeleton set comprises bones from a subset of the various skeletons,
the subset of various skeletons is selected according to a preconfigured rule, and
different skeleton sets are associated with correspondingly different preconfigured rules.

6. The computer-implemented system of claim 1, wherein the instructions comprise settings of the scene, the settings indicating one of several preconfigured rules.

7. The computer-implemented system of claim 6, wherein generating the simulated skeleton further comprises choosing a corresponding one of skeleton sets according to the one of the preconfigured rules indicated in the settings.

8. The computer-implemented system of claim 7, wherein generating the simulated skeleton further comprises:
selecting distinct scaling factors for each bone in the skeleton set chosen; and
modifying the bones of the generic skeleton by the respective scaling factors selected for the bones.

9. The computer-implemented system of claim 7, wherein:
different bones in each skeleton set are categorized into corresponding distributions, and
an individual scaling factor is selected from a respective distribution associated with the corresponding bone.

10. The computer-implemented system of claim 8, wherein modifying the bones comprises:
multiplying a dimension of an individual bone by the corresponding scaling factor to generate a final dimension of the individual bone in the simulated skeleton; and
repeating the multiplying for each bone in the generic skeleton.

11. A computer-implemented system, comprising:
one or more non-transitory computer-readable media storing instructions, when executed by one or more processing units, cause the one or more processing units to perform operations comprising:
retrieving real-world data comprising asset attributes of objects and people in a region;
deriving attribute rules for the asset attributes;
receiving instructions to generate a simulation asset for a scene in a simulation, the simulation asset having a subset of the asset attributes;
generating the simulation asset having characteristics according to attribute rules corresponding to the subset of the asset attributes; and
determining a reaction of a vehicle to the simulation asset in the scene simulated, the reaction of the vehicle being a function of a configuration of the vehicle.

12. The computer-implemented system of claim 11, the operations further comprising:
in response to the reaction, updating the configuration;
repeating determining the reaction and updating the configuration until a desired reaction is obtained; and
exporting a final updated configuration corresponding to the desired reaction to a physical vehicle.

13. The computer-implemented system of claim 12, wherein:
the configuration includes settings of sensors in the vehicle,
determining the reaction is by simulating sensing of the simulation asset by the sensors according to the settings, and
the reaction of the vehicle comprises, in response to the sensing by the sensors, at least one of: (i) movement of the vehicle or (ii) classification of the simulation asset by a control stack of the vehicle.

14. The computer-implemented system of claim 12, wherein:
the configuration includes settings of a control stack of the vehicle,
the determining is by generating control messages by the control stack according to the settings when sensors of the vehicle perceive the simulation asset, and
the reaction of the vehicle comprises movement of the vehicle in response to the control messages by the control stack.

15. The computer-implemented system of claim 11, wherein each simulation asset is associated with at least one distinct attribute distribution.

16. The computer-implemented system of claim 11, wherein:
the instructions to generate the simulation asset are according to settings of the scene,
the settings indicate one or more attribute distributions,
the subset of the asset attributes is associated with a particular one of the attribute distributions, and
the operations further comprise:
identifying the particular one of the attribute distributions indicated by the settings;
identifying the subset of asset attributes associated with the particular one of the attribute distributions; and
generating simulation assets having characteristics corresponding to the subset of the asset attributes according to the attribute rules.

17. A computer-implemented system, comprising:
one or more non-transitory computer-readable media storing instructions, when executed by one or more processing units, cause the one or more processing units to perform operations comprising:
retrieving real-world data comprising appearances of objects in an operational design domain;
receiving instructions to generate a simulation asset comprising an individual one of the objects according to a configuration of a scene;
generating the simulation asset having a parameterized appearance representing one of various possible appearances of the individual one of the objects in the operational design domain; and
determining a reaction of a vehicle to the simulation asset in the scene simulated, the reaction of the vehicle being a function of a configuration of the vehicle.

18. The computer-implemented system of claim 17, the operations further comprising:
in response to the reaction, updating the configuration;
repeating the determining the reaction and the updating the configuration until a desired reaction is obtained; and
exporting a final updated configuration corresponding to the desired reaction to a physical vehicle.

19. The computer-implemented system of claim 18, wherein:
the configuration includes settings of sensors in the vehicle,
the determining is by simulating a sensing of the simulation asset by the sensors according to the settings, and
the reaction of the vehicle comprises, in response to the sensing by the sensors, at least one of: (i) movement of the vehicle or (ii) classification of the simulation asset by a control stack of the vehicle.

20. The computer-implemented system of any one of claim 18, wherein:
the configuration includes settings of a control stack of the vehicle,
the determining is by simulating control messages by the control stack according to the settings when sensors of the vehicle perceive the simulation asset, and
the reaction of the vehicle comprises movement of the vehicle in response to the control messages by the control stack.
